(19) United States
(12) Patent Application Publication
(10) Pub. No.: US 2017/0111011 A1
(43) Pub. Date: Apr. 20, 2017

(54) BALANCED UP-CONVERSION MIXER

(71) Applicant: National Chi Nan University, Puli (TW)

(72) Inventors: Yo-Sheng LIN, Puli (TW); Sin-Chen LIN, Puli (TW); Chien-Chu CHI, Puli (TW)

(21) Appl. No.: 15/079,891

(22) Filed: Mar. 24, 2016

(30) Foreign Application Priority Data
Oct. 15, 2015 (TW) 104133852

(51) Int. Cl. H03D 7/14

(52) U.S. Cl. CPC H03D 7/1441

(57) ABSTRACT

A balanced up-conversion mixer includes: a load circuit permitting a differential radio frequency (DRF) current signal pair (SP) to flow out and outputting a DRF voltage SP based on its impedance, a DC bias voltage and the DRF current SP; a mixing circuit allowing the DRF current SP to flow thereinto based on a differential intermediate frequency voltage SP, a differential oscillating voltage SP generated based on an oscillating voltage signal by a single-ended to differential conversion circuit, and first and second currents generated by a negative resistance compensation circuit based on a DC bias voltage; and a signal amplifier circuit amplifying the DRF voltage SP to generate a differential output voltage SP.

### CROSS-REFERENCE TO RELATED APPLICATION

This application claims priority of Taiwanese Application No. 104133852, filed on Oct. 15, 2015.

### FIELD

The disclosure relates to a mixer, and more particularly to a balanced up-conversion mixer.

### BACKGROUND

Referring to FIG. 1, a conventional balanced up-conversion mixer disclosed in an article by A. Y.-K. Chen, Y. Baeyens, Y.-K. Chen and J. Lin, entitled “An 80 GHz High Gain Double-Balanced Active Up-Conversion Mixer Using 0.18 μm SiGe BiCMOS Technology,” in IEEE Microwave and Wireless Components Letters, vol. 21, no. 6, June 2011, includes a load circuit 11 that is used to receive a direct current (DC) bias voltage (VCC), a mixing circuit 12 and a signal amplifier circuit 13.

The mixing circuit 12 includes a current source 121, a transduction unit 122 and a mixing unit 123.

The current source 121 receives a bias voltage (Vb), and is use to modulate a total bias current flowing therethrough. The transduction unit 122 is coupled between the current source 121 and the mixing unit 123, and is used to receive a differential intermediate frequency (IF) voltage signal pair that consists of positive-phase and negative-phase IF voltage signals. The transduction unit 122 is operative to allow a differential IF current signal pair to flow into the current source 121 therethrough based on the differential IF voltage signal pair. The differential IF current signal pair constitutes the total bias current, and consists of positive-phase and negative-phase IF current signals (I11, I12). The mixing unit 123 is coupled between the transduction unit 122 and the load circuit 11, and is used to receive a differential oscillating voltage (OV) signal pair that consists of positive-phase and negative-phase OV signals. The mixing unit 123 is operative to allow, based on the differential OV signal pair, a differential radio frequency (RF) current signal pair flowing through the load circuit 11 to flow therethrough and into the transduction unit 122. The differential RF current signal pair consists of positive-phase and negative-phase RF current signals (I21, I22), and serves as the differential IF current signal pair.

The load circuit 11 outputs a differential RF voltage signal pair based on its impedance and on the positive-phase and negative-phase RF current signals (I21, I22). The signal amplifier circuit 13 is coupled to the load circuit 11 for receiving the differential RF voltage signal pair therefrom. The signal amplifier circuit 13 amplifies the differential RF voltage signal pair so as to generate a positive-phase output voltage signal and a negative-phase output voltage signal.

In such a configuration, upon DC analysis, since the current flowing into the transduction unit 122 flows entirely through the load circuit 11, power consumed by the load circuit 11 is relatively high. In addition, the conventional balanced up-conversion mixer typically improves its self-conversion gain by increasing its power requirements. As a result, the conventional balanced up-conversion mixer may have a further increased power consumption. In other words, the conventional balanced up-conversion mixer cannot obtain a high conversion gain at low power consumption.

### SUMMARY

Therefore, an object of the disclosure is to provide a balanced up-conversion mixer that can overcome the drawbacks of the prior art.

According to the disclosure, the balanced up-conversion mixer includes a single-ended to differential conversion circuit, a negative resistance compensation circuit, a load circuit, a mixing circuit and a signal amplifier circuit.

The single-ended to differential conversion circuit is used to receive an oscillating voltage signal, and is configured to generate a differential oscillating voltage signal pair based on the oscillating voltage signal.

The negative resistance compensation circuit is used to receive a direct current (DC) bias voltage, and is configured to generate and output a first current and a second current based on the DC bias voltage.

The load circuit is used to receive the DC bias voltage, and is configured to permit a differential radio frequency (RF) current signal pair to flow out of the load circuit and to output a differential RF voltage signal pair based on an impedance thereof, the DC bias voltage and the differential RF current signal pair.

The mixing circuit is used to receive a differential intermediate frequency (IF) voltage signal pair, and is coupled to the single-ended to differential conversion circuit for receiving the differential oscillating voltage signal pair therefrom, to the negative resistance compensation circuit for receiving the first and second currents therefrom and to the load circuit for receiving the differential RF current signal pair therefrom. The mixing circuit is configured to allow the RF current signal pair to flow thereinto based on the differential IF voltage signal pair, the differential oscillating voltage signal pair and the first and second currents.

The signal amplifier circuit is used to receive the DC bias voltage, and is coupled to the load circuit for receiving the differential RF voltage signal pair therefrom. The signal amplifier circuit is configured to amplify the differential RF voltage signal pair so as to generate a differential output voltage signal pair.

The differential RF voltage signal pair has a frequency associated with those of the differential oscillating voltage signal pair and the differential IF voltage signal pair.

### BRIEF DESCRIPTION OF THE DRAWINGS

Other features and advantages of the disclosure will become apparent in the following detailed description of the embodiment with reference to the accompanying drawings, of which:

FIG. 1 is a schematic electrical circuit diagram illustrating a conventional balanced up-conversion mixer;

FIG. 2 is a schematic block diagram illustrating an embodiment of a balanced up-conversion mixer according to the disclosure; and

FIG. 3 is a schematic electrical circuit diagram of the embodiment;

FIG. 4 is a plot illustrating experimental measurement results of a differential radio frequency voltage signal pair, a differential intermediate frequency voltage signal pair and a differential oscillating voltage signal pair of the embodiment;

FIG. 5 is a schematic diagram showing an exemplary structure of a 1-underneath metal Marchand balun; and

FIG. 6 is a schematic diagram showing an exemplary conventional structure of a 3-underneath metal Marchand balun.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

In addition, when two elements are described as being “coupled in series,” “connected in series” or the like, it is merely intended to portray a serial connection between the two elements without necessarily implying that the currents flowing through the two elements are identical to each other and without limiting whether or not an additional element is coupled to a common node between the two elements. Essentially, “a series connection of elements,” “a series coupling of elements” or the like as used throughout this disclosure should be interpreted as being such when looking at those elements alone.

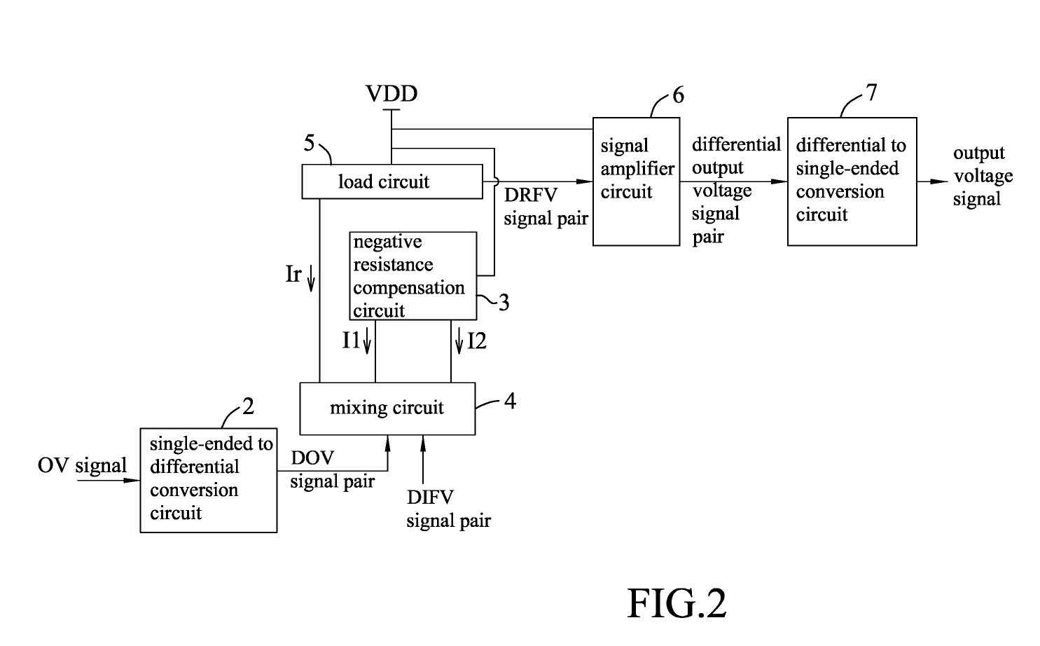

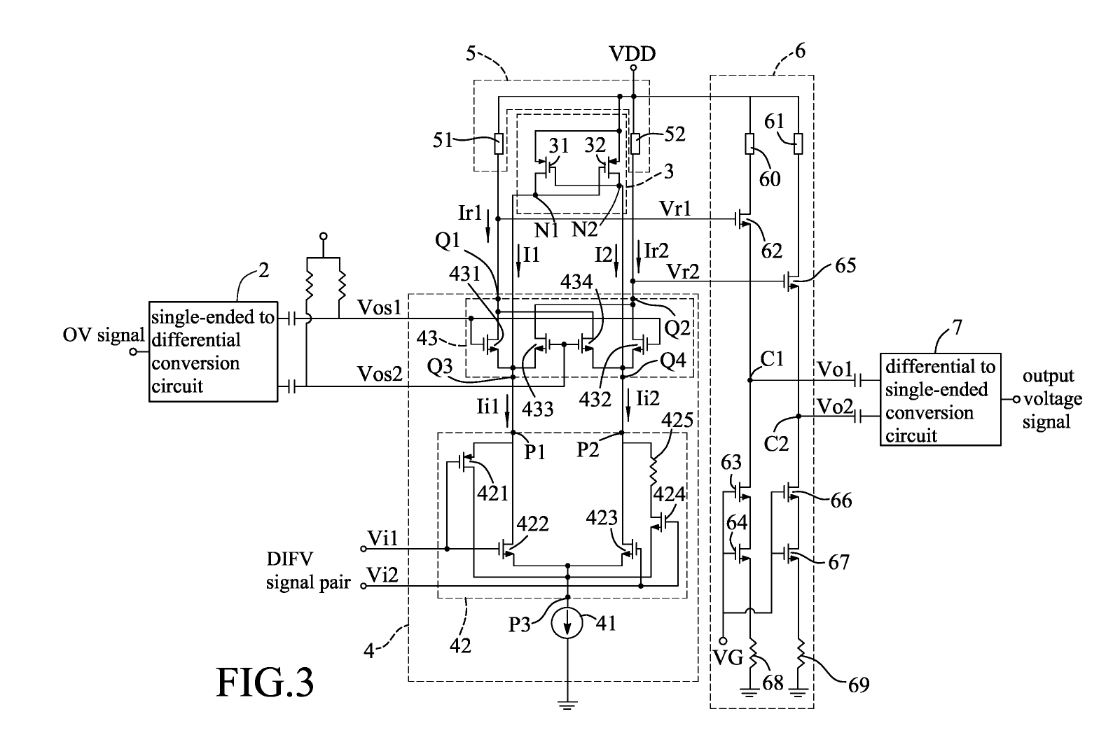

Referring to FIGS. 2 and 3, an embodiment of a balanced up-conversion mixer according to the disclosure is shown to include a single-ended to differential conversion circuit 2, a negative resistance compensation circuit 3, a mixing circuit 4, a load circuit 5, a signal amplifier circuit 6 and a differential to single-ended conversion circuit 7.

The single-ended to differential conversion circuit 2 is used to receive an oscillating voltage (OV) signal, and is configured to generate a differential oscillating voltage (DOV) signal pair based on the OV signal. In this embodiment, the DOV signal pair consists of positive-phase and negative-phase OV signals (Vos1, Vos2).

The negative resistance compensation circuit 3 is used to receive a direct current (DC) bias voltage (VDD), and is configured to generate and output first and second currents (I1, I2) based on the DC bias voltage (VDD). In this embodiment, the negative resistance compensation circuit 3 includes a first transistor 31 and a second transistor 32.

Each of the first and second transistors 31, 32 has a first terminal, a second terminal and a control terminal. The first terminals of the first and second transistors 31, 32 are coupled with each other to receive the DC bias voltage (VDD). The control terminals of the first and second transistors 31, 32 are coupled respectively to the second terminals of the second and first transistors 32, 31. The first and second currents (I1, I2) flow out of the negative resistance compensation circuit 3 respectively through a common node (N1) between the second terminal of the first transistor 31 and the control terminal of the second transistor 32, and a common node (N2) between the control terminal of the first transistor 31 and the second terminal of the second transistor 32. It should be noted that each of the first and second transistors 31, 32 is, for example, a P-type metal-oxide-semiconductor field effect transistor (MOSFET), which has a source, a drain and a gate serving respectively as the first, second and control terminals thereof.

The mixing circuit 4 is coupled to the single-ended to differential conversion circuit 2 for receiving the DOV signal pair therefrom, and to the negative resistance compensation circuit 3 for receiving the first and second currents (I1, I2) therefrom. The mixing circuit 4 is used to further receive a differential intermediate frequency voltage (DIFV) signal pair. The mixing circuit 4 is configured to allow, based on the DIFV signal pair, on the DOV signal pair and on the first and second currents (I1, I2), a differential radio frequency current (DRFC) signal pair (Ir) flowing through the load circuit 5 to flow thereinto. It should be noted that the DIFV signal pair used in this embodiment may be generated in a known manner. The DIFV signal pair consists of positive-phase and negative-phase IFV signals (Vi1, Vi2). The DRFC signal pair (Ir) consists of positive-phase and negative-phase radio frequency current (RFC) signals (Ir1, Ir2).

In this embodiment, the mixing circuit 4 includes a current source 41, a transduction unit 42 and a mixing unit 43.

The current source 41 is configured to modulate a total bias current flowing therethrough. The transduction unit 42 is coupled between the current source 41 and the negative resistance compensation circuit 3. The transduction unit 42 is used to receive the DIFV signal pair, and is configured to allow, based on the DIFV signal pair, a differential intermediate frequency current (DIFC) signal pair to flow therethrough and into the current source 41. In this case, the DIFC signal pair serves as the total bias current, and includes the first and second currents (I1, I2) from the negative resistance compensation circuit 3. The DIFC signal pair consists of positive-phase and negative-phase intermediate frequency current (IFC) signals (Ii1, Ii2). In this embodiment, the transduction unit 42 includes first and second input nodes (P1, P2), an output node (P3), first to fourth transistors 421, 422, 423, 424 and a resistor 425.

The first and second input nodes (P1, P2) are coupled respectively to the common nodes (N1, N2) of the negative resistance compensation circuit 3. The positive-phase and negative-phase IFC signals (Ii1, Ii2) flow into the transduction unit 42 respectively through the first and second input nodes (P1, P2). The output node (P3) is coupled to the current source 41. The DIFC signal pair flows out of the transduction unit 42 through the output node (P3) and flows into the current source 41. Each of the first and second transistors 421, 422 has a first terminal that is coupled to the first input node (P1), a second terminal that is coupled to the output node (P3), and a control terminal that is used to receive the positive-phase IFV signal (Vi1) such that the first and second transistors 421, 422 are operable to be conducting or non-conducting in response to the positive-phase IFV signal (Vi1). The third transistor 423 has a first terminal that is coupled to the second input node (P2), and a second terminal that is coupled to the output node (P3). The fourth transistor 424 and the resistor 425 are coupled in series between the second input node (P2) and the output node (P3). The fourth transistor 424 has a first terminal that is coupled to the resistor 425, a second terminal that is coupled to the output terminal (P3). Each of the third and fourth transistors 423, 424 further has a control terminal that is used to receive the negative-phase IFV signal (Vi2) such that the third and fourth transistors 423, 424 are operable to be conducting or non-conducting in response to the negative-phase IFV signal (Vi2). It should be noted that the first transistor 421 is, for example, a P-type MOSFET, which has a source, a drain and a gate serving respectively as the first, second and control terminals thereof. Each of the second to fourth transistors 422, 423, 424 is, for example, an N-type MOSFET, which has a drain, a source and a gate serving respectively as the first, second and control terminals thereof.

The mixing unit 43 is coupled to the transduction unit 42, the load circuit 5 and the single-ended to differential conversion circuit 2. The mixing unit 43 receives the DOV signal pair from the single-ended to differential conversion circuit 2. The mixing unit 43 is configured to allow, based on the DOV signal pair, the DRFC signal pair (Ir) from the load circuit 5 to flow therethrough and into the transduction unit 42. In this embodiment, the mixing unit 43 includes first and second input nodes (Q1, Q2), first and second output nodes (Q3, Q4), and first to fourth transistors 431, 432, 433, 434.

The first and second input nodes (Q1, Q2) are coupled to the load circuit 5. The positive-phase and negative-phase RFC signals (Ir1, Ir2) flow into the mixing unit 43 respectively through the first and second input nodes (Q1, Q2). The first and second output nodes (Q3, Q4) are coupled respectively to the first and second input nodes (P1, P2) of the transduction unit 42. The first transistor 431 is coupled between the first input node (Q1) and the first output node (Q3). The second transistor 432 is coupled between the second input node (Q2) and the second output node (Q4). Each of the first and second transistors 431, 432 has a control terminal that is used to receive the positive-phase OV signal (Vos1) such that the first and second transistors 431, 432 are operable to be conducting or non-conducting in response to the positive-phase OV signal (Vos1). The third transistor 433 is coupled between the second input node (Q2) and the first output node (Q3). The fourth transistor 434 is coupled between the first input node (Q1) and the second output node (Q4). Each of the third and fourth transistors 433, 434 has a control terminal that is used to receive the negative-phase OV signal (Vos2) such that the third and fourth transistors 433, 434 are operable to be conducting or non-conducting in response to the negative-phase OV signal (Vos2). It should be noted that each of the first to fourth transistors 431, 432, 433, 434 further has a first terminal and a second terminal. The first and second terminals of the first transistor 431 are coupled respectively to the first input node (Q1) and the first output node (Q3). The first and second terminals of the second transistor 432 are coupled respectively to the second input node (Q2) and the second output node (Q4). The first and second terminals of the third transistor 433 are coupled respectively to the second input node (Q2) and the first output node (Q3). The first and second terminals of the fourth transistor 434 are coupled respectively to the first input node (Q1) and the second output node (Q4). In this embodiment, each of the first to fourth transistors 431, 432, 433, 434 is, for example, an N-type MOSFET, which has a drain, a source and a gate serving respectively as the first, second and control terminals thereof.

When the first and second transistors 431, 432 conduct in response to the positive-phase OV signal (Vos1) while the third and fourth transistors 433, 434 do not conduct in response to the negative-phase OV signal (Vos2), the positive-phase and negative-phase RFC signals (Ir1, Ir2) flow out of the mixing unit 43 respectively through the first and second output nodes (Q3, Q4) and flow into the transduction unit 42. In this case, the positive-phase RFC signal (Ir1) and the first current (I1) cooperatively constitute the positive-phase IFC signal (Ii1), and the negative-phase RFC signal (Ir2) and the second current (I2) cooperatively constitute the negative-phase IFC signal (Ii2). When the first and second transistors 431, 432 do not conduct in response to the positive-phase OV signal (Vos1) while the third and fourth transistors 433, 434 conduct in response to the negative-phase OV signal (Vos2), the positive-phase and negative-phase RFC signals (Ir1, Ir2) flow out of the mixing unit 43 respectively through the second and first output nodes (Q4, Q3) and flow into the transduction unit 42. In this case, the negative-phase RFC signal (Ir2) and the first current (I1) cooperatively constitute the positive-phase IFC signal (Ii1), and the positive-phase RFC signal (Ir1) and the second current (I2) cooperatively constitute the negative-phase IFC signal (Ii2).

The load circuit 5 is used to receive the DC bias voltage (VDD), and is configured to permit the DRFC signal pair (Ir) to flow out of the load circuit 5 and to output a differential radio frequency voltage (DRFV) signal pair based on its impedance, the DC bias voltage (VDD) and the DRFC signal pair (Ir). The DRFV signal pair has a frequency associated with a frequency of the DOV signal pair and a frequency of the DIFV signal pair. It is noted that the frequency of the DRFV signal pair is, but not limited to, a sum of the frequencies of the DOV and DIFV signal pairs. For example, if the frequency of the DOV signal pair is 93.9 GHz and the frequency of the DIFV signal pair is 0.1 GHz, then the frequency of the DRFV signal pair would be 94 GHz (=93.9 GHz+0.1 GHz).

In this embodiment, the DRFV signal pair consists of positive-phase and negative-phase radio frequency voltage (RFV) signals (Vr1, Vr2). The load circuit 5 includes first and second inductors 51, 52. Each of the first and second inductors 51, 52 has opposite first and second terminals. The first terminals of the first and second inductors 51, 52 are coupled with each other to receive the DC bias voltage (VDD). The second terminals of the first and second inductors 51, 52 are coupled respectively to the first and second input nodes (Q1, Q2) of the mixing unit 43. The load circuit 5 outputs the positive-phase and negative-phase RFV signals (Vr1, Vr2) respectively at the second terminals of the first and second inductors 51, 52. It is noted that each of the first and second inductors 51, 52 is, for example, a transmission line inductor.

The signal amplifier circuit 6 is used to receive the DC bias voltage (VDD), and is coupled to the load circuit 5 for receiving the positive-phase and negative-phase RFV signals (Vr1, Vr2) therefrom. The signal amplifier circuit 6 is configured to amplify the positive-phase and negative-phase RFV signals (Vr1, Vr2) so as to generate a differential output voltage signal pair. In this embodiment, the differential output voltage signal pair consists of positive-phase and negative-phase output voltage signals (Vo1, Vo2). The signal amplifier circuit 6 includes first and second inductors 60, 61, first to sixth transistors 62-67 and first and second resistors 68, 69.

The first inductor 60, the first to third transistors 62, 63, 64 and the first resistor 68 are coupled in series. The first inductor 60 is used to receive the DC bias voltage (VDD). The first transistor 62 is coupled between the first inductor 60 and the second transistor 63. The first transistor 62 has a control terminal that is coupled to the load circuit 5 for receiving the positive-phase RFV signal (Vr1) therefrom such that the first transistor 62 is operable to be conducting or non-conducting in response to the positive-phase RFV signal (Vr1). The third transistor 64 is coupled between the second transistor 63 and the first resistor 68. Each of the second and third transistors 63, 64 has a control terminal that is used to receive a control signal (VG) such that the second and third transistors 63, 64 are operable to be conducting or non-conducting in response to the control signal (VG). The first resistor 68 is coupled between the third transistor 64 and ground. The positive-phase output voltage signal (Vo1) is outputted at a first common node (C1) between the first transistor 62 and the second transistor 63. The second inductor 61, the fourth to sixth transistors 65, 66, 67 and the second resistor 69 are coupled in series. The second inductor 61 is used to receive the DC bias voltage (VDD). The fourth transistor 65 is coupled between the second inductor 61 and the fifth transistor 66. The fourth transistor 65 has a control terminal that is coupled to the load circuit 5 for receiving the negative-phase RFV signal (Vr2) therefrom such that the fourth transistor 65 is operable to be conducting or non-conducting in response to the negative-phase RFV signal (Vr2). The sixth transistor 67 is coupled between the fifth transistor 66 and the second resistor 69. Each of the fifth and sixth transistors 66, 67 has a control terminal that is used to receive the control signal (VG) such that the fifth and sixth transistors 66, 67 are operable to be conducting or non-conducting in response to the control signal (VG). The second resistor 69 is coupled between the sixth transistor 67 and ground. The negative-phase output voltage signal (Vo2) is outputted at a second common node (C2) between the fourth transistor 65 and the fifth transistor 66.

The differential to single-ended conversion circuit 7 is coupled to the signal amplifier circuit 6 for receiving the positive-phase and negative-phase output voltage signals (Vo1, Vo2) therefrom, and is configured to generate an output voltage signal based on the positive-phase and negative-phase output voltage signals (Vo1, Vo2).

A conversion gain of the balanced up-conversion mixer can be expressed by the following equation:

$$CG = \frac{2}{π} \frac{{G}_{m , L O}}{( {G}_{m , LO} - {g}_{m 31 , 32} )} {g}_{m 421 , 422 , 423 , 424} {ω}_{RF} L$$

where CG represents the conversion gain, G_{m,Lo} represents an equivalent input transconductance of the first and third transistors 431, 433 at the first output node (Q3) or an equivalent input transconductance of the second and fourth transistors 432, 434 at the second output node (Q4), g_{m31,32} is an equivalent input transconductance of the first and second transistors 31, 32, g_{m421,422,423,424} is an equivalent input transconductance of the first to fourth transistors 421-424, ω_{RF} is an operating frequency of the balanced up-conversion mixer (i.e., the frequency of the DRFV signal pair of, for example, 94 GHz), L is an inductance of one of the first and second inductors 51, 52.

It is known from the equation that the conversion gain (CG) increases with increase of at least one of the transconductance (g_{m31,32}), which is smaller than the equivalent input transconductance (G_{m,Lo}), and the transconductance (g_{m421,422,423,424}).

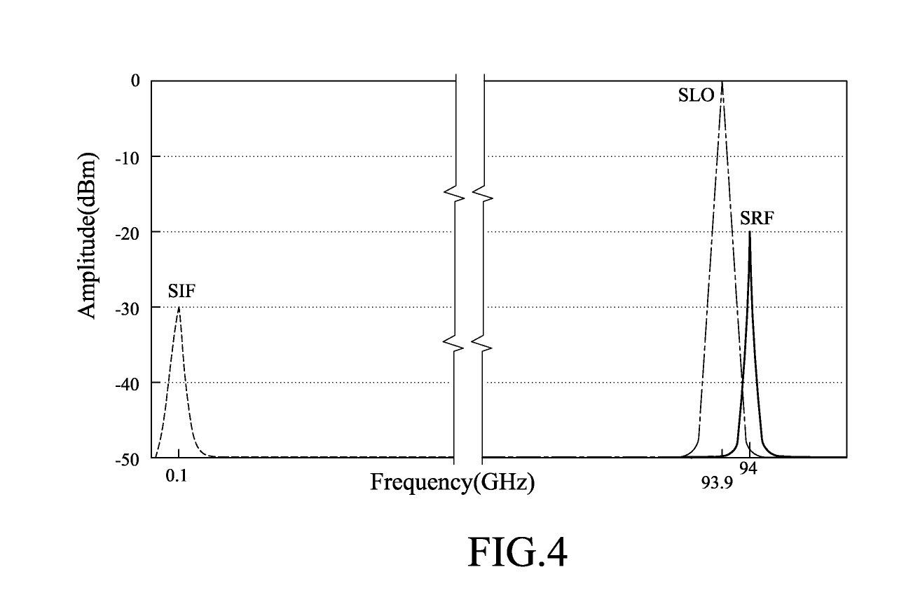

FIG. 4 illustrates experimental measurement results of the embodiment, in which: the solid curve (SRF) represents the DRFV signal pair; the dashed curve (SIF) represents the DIFV signal pair; and the long-dash-short-dash curve (SLO) represents the DOV signal pair. From the experimental measurements results of FIG. 4, the frequency of the DRFV signal pair is the sum of the frequencies of the DOV and DIFV signal pairs.

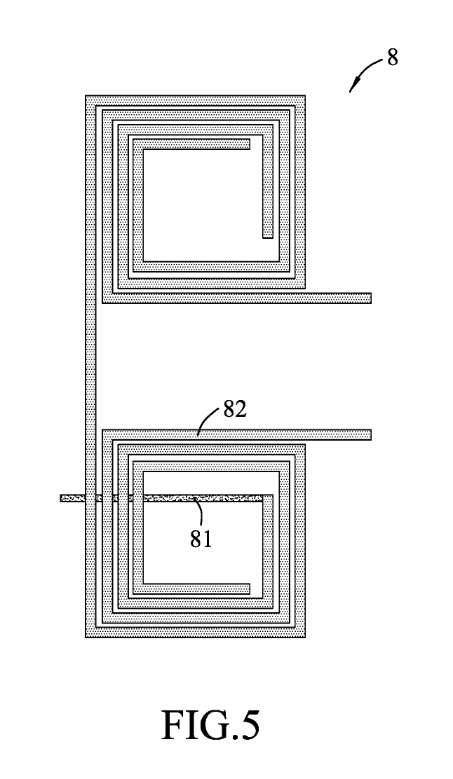

FIG. 5 illustrates an exemplary structure for each of the single-ended to differential conversion circuit 2 (see FIG. 2) and the differential to single-ended conversion circuit 7 (see FIG. 2). In this embodiment, each of the single-ended to differential conversion circuit 2 and the differential to single-ended conversion circuit 7 is, for example, a 1-underneath metal Marchand balun 8, which includes a bottom metal 81 and atop metal 82. The thickness of the bottom metal 81 is 0.85 μm. The thickness of the top metal 82 is 3.4 μm.

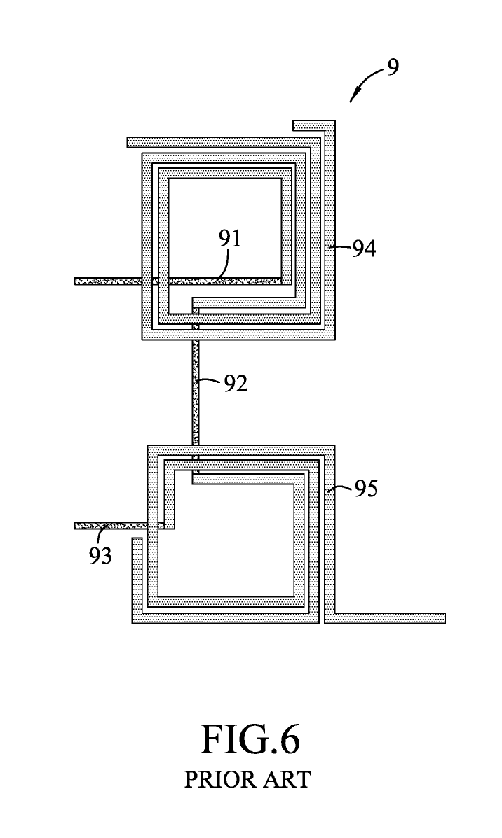

FIG. 6 illustrates an exemplary conventional structure for each of the single-ended to differential conversion circuit 2 (see FIG. 2) and the differential to single-ended conversion circuit 7 (see FIG. 2). Herein, each of the single-ended to differential conversion circuit 2 and the differential to single-ended conversion circuit 7 is, for example, a 3-underneath metal Marchand balun 9, which includes first to third bottom metals 91, 92, 93 and first and second top metals 94, 95. The thickness of each of the first to third bottom metals 91, 92, 93 is 0.85 μm. The thickness of each of the first and second top metals 94, 95 is 3.4 μm.

It should be noted that since the thickness of each of the bottom metals 81, 91, 92, 93 is thinner, each of the bottom metals 81, 91, 92, 93 has a higher power loss. Therefore, by reducing the number of the bottom metals, the power loss of the single-ended to differential conversion circuit 2 and/or the differential to single-ended conversion circuit 7 can be reduced. When the single-ended to differential conversion circuit 2 and the differential to single-ended conversion circuit 7 are implemented by 1-underneath metal Marchand baluns 8 each only having one bottom metal 81, the balanced up-conversion mixer may have a smaller power loss as compared to when the single-ended to differential conversion circuit 2 and the differential to single-ended conversion circuit 7 are implemented using 3-underneath metal Marchand baluns 9.

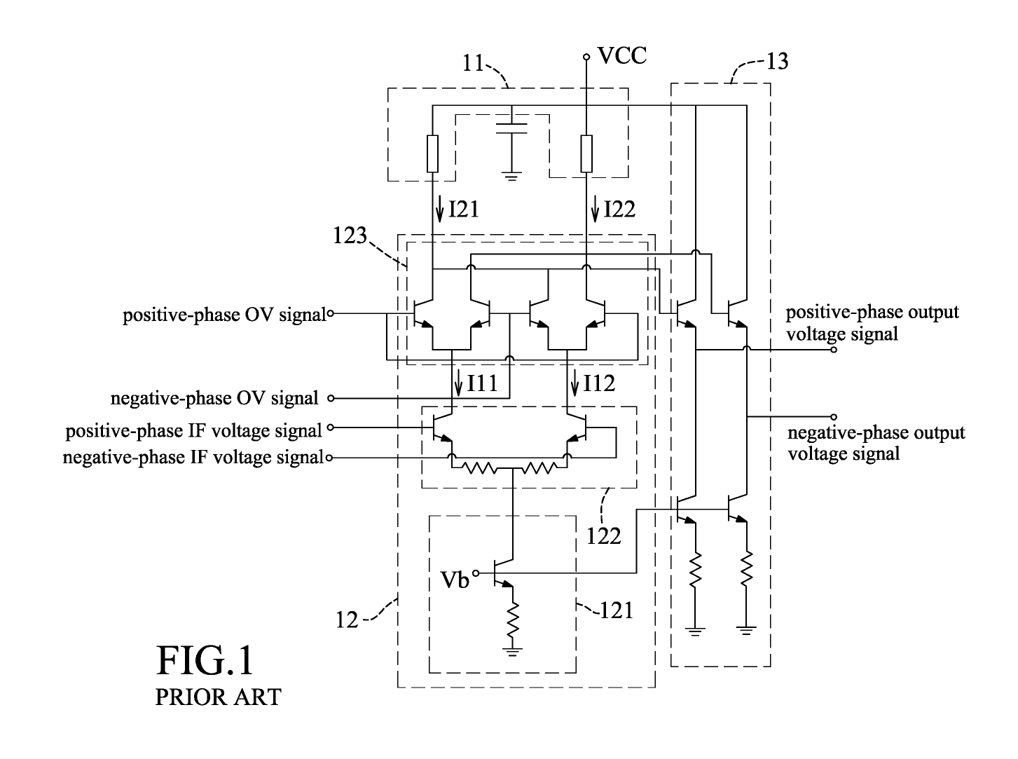

Measurement results of the balanced up-conversion mixer of this disclosure with the single-ended to differential conversion circuit 2 and the differential to single-ended conversion circuit 7 implemented using 1-underneath metal Marchand baluns 8 and of the conventional balanced up-conversion mixer depicted in FIG. 1 are shown in Table 1. It is known from Table that the balanced up-conversion mixer of this disclosure is able to simultaneously achieve high conversion gain and low power consumption.

TABLE 1

| | | the |
|---|---|---|
| | the balanced | conventional |
| | up-conversion | balanced |
| | mixer of this | up-conversion |
| | disclosure | mixer |
| frequency of the DRFV | 94 | 80 |
| signal pair (GHz) | | |
| frequency of the DIFV | 0.1 | 0.01 |
| signal pair (GHz) | | |
| Conversion Gain (dB) | 15.55 | 3.2 |
| Power Consumption (mW) | 7.62 | 104 |

To sum up, upon DC analysis, since the DIFC signal pair consists of the DRFC signal pair (Ir) and the first and second currents (I1, I2), the load circuit 5 of this disclosure consumes relatively low power as compared to the load circuit 11 of FIG. 1. In addition, since the conversion gain (CG) changes with change of the transconductances (g_{m31,32}, g_{m421,422,423,424}), the conversion gain (CG) of the balanced up-conversion mixer of this disclosure can be easily increased by appropriately selecting the transistors 31, 32, 421-424 without increasing power consumption as is the case with the conventional balanced up-conversion mixer. Furthermore, each of the single-ended to differential conversion circuit 2 and the differential to single-ended conversion circuit 7 of this disclosure is the 1-underneath metal Marchand balun 8. Accordingly, the power loss of the balanced up-conversion mixer of this disclosure can be reduced.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects.

While the disclosure has been described in connection with what is considered the exemplary embodiment, it is understood that this disclosure is not limited to the disclosed embodiment but is intended to cover various arrangements included within the spirit and scope of the broadest interpretation so as to encompass all such modifications and equivalent arrangements.

1. A balanced up-conversion mixer comprising:
a single-ended to differential conversion circuit used to receive an oscillating voltage signal, and configured to generate a differential oscillating voltage signal pair based on the oscillating voltage signal;
a negative resistance compensation circuit used to receive a direct current (DC) bias voltage, and configured to generate and output a first current and a second current based on the DC bias voltage;
a load circuit used to receive the DC bias voltage, and configured to permit a differential radio frequency (RF) current signal pair to flow out of said load circuit and to output a differential RF voltage signal pair based on an impedance thereof, the DC bias voltage and the differential RF current signal pair;
a mixing circuit used to receive a differential intermediate frequency (IF) voltage signal pair that includes a positive-phase IF voltage signal and a negative-phase IF voltage signal, said mixing circuit being coupled to said single-ended to differential conversion circuit for receiving the differential oscillating voltage signal pair therefrom, to said negative resistance compensation circuit for receiving the first and second currents therefrom and to said load circuit for receiving the differential RF current signal pair therefrom, said mixing circuit being configured to allow the RF current signal pair to flow thereinto based on the differential IF voltage signal pair, the differential oscillating voltage signal pair and the first and second currents; and
a signal amplifier circuit used to receive the DC bias voltage, and coupled to said load circuit for receiving the differential RF voltage signal pair therefrom, said signal amplifier circuit being configured to amplify the differential RF voltage signal pair so as to generate a differential output voltage signal pair;
wherein the differential RF voltage signal pair has a frequency associated with those of the differential oscillating voltage signal pair and the differential IF voltage signal pair;
wherein said mixing circuit includes
a current source configured to modulate a total bias current flowing therethrough,
a transduction unit coupled between said current source and said negative resistance compensation circuit and used to receive the differential IF voltage signal pair, said transduction unit being configured to allow, based on the differential IF voltage signal pair, a differential IF current signal pair to flow therethrough and into said current source, the differential IF current signal pair including the first and second currents and serving as the total bias current, and
a mixing unit coupled to said transduction unit, said load circuit and said single-ended to differential conversion circuit and receiving the differential oscillating voltage signal pair from said single-ended to differential conversion circuit, said mixing unit being configured to allow, based on the differential oscillating voltage signal pair, the differential RF current signal pair from said load circuit to flow therethrough and into said transduction unit, the differential RF current signal pair and the first and second currents cooperatively constituting the differential IF current signal pair;
wherein the differential IF current signal pair includes a positive-phase IF current signal and a negative-phase IF current signal;
wherein said transduction unit includes
a first input node and a second input node coupled to said mixing unit and said negative resistance compensation circuit, the positive-phase and negative-phase IF current signals flowing into said transduction unit respectively through said first and second input nodes,
an output node coupled to said current source, the differential IF current signal pair flowing out of said transduction unit through said output node to flow into said current source,
a first transistor and a second transistor, each of which has a first terminal coupled to said first input node, a second terminal coupled to said output node, and a control terminal used to receive the positive-phase IF voltage signal such that each of said first and second transistors is operable to be conducting or non-conducting in response to the positive-phase IF voltage signal,
a third transistor having a first terminal coupled to said second input node, a second terminal coupled to said output node, and a control terminal used to receive the negative-phase IF voltage signal such that said third transistor is operable to be conducting or non-conducting in response to the negative-phase IF voltage signal, and
a fourth transistor and a resistor coupled in series between said second input node and said output node, said fourth transistor having a first terminal coupled to said resistor, a second terminal coupled to said output terminal, and a control terminal used to receive the negative-phase IF voltage signal such that said fourth transistor is operable to be conducting or non-conducting in response to the negative-phase IF voltage signal.

2. The balanced up-conversion mixer of claim 1, wherein said negative resistance compensation circuit includes:
a first transistor and a second transistor, each of which has a first terminal, a second terminal and a control terminal, each of said first terminals of said first and second transistors being used to receive the DC bias voltage, said control terminal of said first transistor being coupled to said second terminal of said second transistor, said control terminal of said second transistor being coupled to said second terminal of said first transistor, the first and second currents flowing out of said negative resistance compensation circuit respectively through a common node between said second terminal of said first transistor and said control terminal of said second transistor, and a common node between said control terminal of said first transistor and said second terminal of said second transistor.

3. The balanced up-conversion mixer of claim 1, wherein:
the differential RF voltage signal pair includes a positive-phase RF voltage signal and a negative-phase RF voltage signal; and
said load circuit includes a first inductor and a second inductor, each of which has opposite first and second terminals, each of said first terminals of said first and second inductors being used to receive the DC bias voltage, said second terminals of said first and second inductors being configured to respectively output the positive-phase RF voltage signal and the negative-phase RF voltage signal.

4. (canceled)

5. (canceled)

6. The balanced up-conversion mixer of claim 1, wherein:
said first transistor is a P-type metal-oxide-semiconductor field effect transistor (MOSFET) having a source, a drain and a gate that respectively serve as said first terminal, said second terminal and said control terminal of said first transistor; and
each of said second to fourth transistors is an N-type MOSFET having a drain, a source and a gate that respectively serve as said first terminal, said second terminal and said control terminal of the corresponding one of said second to fourth transistors.

7. The balanced up-conversion mixer of claim 1, wherein:
the differential oscillating voltage signal pair includes a positive-phase oscillating voltage signal and a negative-phase oscillating voltage signal, and the differential RF current signal pair includes a positive-phase RF current signal and a negative-phase RF current signal; and
said mixing unit includes
a first input node and a second input node coupled to said load circuit, the positive-phase and negative-phase RF current signals flowing into said mixing unit respectively through said first and second input nodes,
a first output node and a second output node coupled to said transduction unit, the differential RF current signal pair flowing out of said mixing unit through said first and second output nodes to flow into said transduction unit,
a first transistor coupled between said first input node and said first output node, said first transistor having a control terminal used to receive the positive-phase oscillating voltage signal such that said first transistor is operable to be conducting or non-conducting in response to the positive-phase oscillating voltage signal,
a second transistor coupled between said second input node and said second output node, said second transistor having a control terminal used to receive the positive-phase oscillating voltage signal such that said second transistor is operable to be conducting or non-conducting in response to the positive-phase oscillating voltage signal,
a third transistor coupled between said second input node and said first output node, said third transistor having a control terminal used to receive the negative-phase oscillating voltage signal such that said third transistor is operable to be conducting or non-conducting in response to the negative-phase oscillating voltage signal, and
a fourth transistor coupled between said first input node and said second output node, said fourth transistor having a control terminal used to receive the negative-phase oscillating voltage signal such that said fourth transistor is operable to be conducting or non-conducting in response to the negative-phase oscillating voltage signal.

8. The balanced up-conversion mixer of claim 1, wherein:
the differential RF voltage signal pair includes a positive-phase RF voltage signal and a negative-phase RF voltage signal, and the differential output voltage signal pair includes a positive-phase output voltage signal and a negative-phase output voltage signal; and
said signal amplifier circuit includes
a series connection of a first inductor, a first transistor, a second transistor, a third transistor and a first resistor, said first inductor being used to receive the DC bias voltage, said first transistor being coupled between said first inductor and said second transistor, and having a control terminal coupled to said load circuit for receiving the positive-phase RF voltage signal therefrom such that said first transistor is operable to be conducting or non-conducting in response to the positive-phase RF voltage signal, said third transistor being coupled between said second transistor and said first resistor, each of said second and third transistors having a control terminal used to receive a control signal such that each of said second and third transistors is operable to be conducting or non-conducting in response to the control signal, said first resistor being coupled between said third transistor and ground, the positive-phase output voltage signal being outputted at a first common node between said first transistor and said second transistor; and
a series connection of a second inductor, a fourth transistor, a fifth transistor, a sixth transistor and a second resistor, said second inductor being used to receive the DC bias voltage, said fourth transistor being coupled between said second inductor and said fifth transistor, and having a control terminal coupled to said load circuit for receiving the negative-phase RF voltage signal therefrom such that said fourth transistor is operable to be conducting or non-conducting in response to the negative-phase RF voltage signal, said sixth transistor being coupled between said fifth transistor and said second resistor, each of said fifth and sixth transistors having a control terminal used to receive the control signal such that each of said fifth and sixth transistors is operable to be conducting or non-conducting in response to the control signal, said second resistor being coupled between said sixth transistor and ground, the negative-phase output voltage signal being outputted at a second common node between said fourth transistor and said fifth transistor.

9. The balanced up-conversion mixer of claim 1, further comprising a differential to single-ended conversion circuit coupled to said signal amplifier circuit for receiving the differential output voltage signal pair therefrom, said differential to single-ended conversion circuit being configured to generate an output voltage signal based on the differential output voltage signal pair.

10. The balanced up-conversion mixer of claim 9, wherein each of said single-ended to differential conversion circuit and said differential to single-ended conversion circuit is a 1-underneath metal Marchand balun.
